(19) United States
(12) Patent Application Publication
(10) Pub. No.: US 2012/0236508 A1
(43) Pub. Date: Sep. 20, 2012

(54) ELECTRONIC-COMPONENT EMBEDDED RESIN SUBSTRATE AND ELECTRONIC CIRCUIT MODULE

(75) Inventor: Masashi ARAI, Nagaokakyo-shi (JP)

(73) Assignee: MURATA MANUFACTURING CO., LTD., Nagaokakyo-shi (JP)

(21) Appl. No.: 13/485,958

(22) Filed: Jun. 1, 2012

Related U.S. Application Data
(63) Continuation of application No. PCT/JP2010/072130, filed on Dec. 9, 2010.

(30) Foreign Application Priority Data
Dec. 9, 2009 (JP) 2009-279412

(51) Int. Cl. H05K 7/06; H05K 1/16

(52) U.S. Cl. 361/728; 174/251

(57) ABSTRACT

An electronic component includes hollow vias provided within a resin layer such that first ends thereof extend to solders which connect and secure an embedded electronic component, and second ends thereof are sealed by a sealing-member layer, in order to cause the solders that become molten again to flow into the hollow vias such that the solders that have become molten again are housed in the hollow vias, thereby suppressing and preventing the occurrence of solder splash phenomena.

### BACKGROUND OF THE INVENTION

1. Field of the Invention

The present invention relates to electronic-component embedded resin substrates including electronic components embedded in resin layers and, more particularly, relates to electronic-component embedded resin substrates which use solders for mounting electronic components embedded therein.

Further, the present invention relates to electronic circuit modules including electronic-component embedded resin substrates as described above.

2. Description of the Related Art

Conventionally, there have been used electronic-component embedded resin substrates including electronic components embedded in resin layers, for coping with demands for higher-density mounting of electronic components. FIG. 12 illustrates an example of a conventionally-used electronic-component embedded resin substrate. This electronic-component embedded resin substrate 600 is formed by connecting and securing, by solders 105a and 105b, terminal electrodes 104a and 104b of an electronic component 103 to land electrodes 102a and 102b formed on a core substrate 101, and providing a resin layer 106 on the core substrate 101 so as to cover the electronic component 103. Although not illustrated, for example, electronic components are further mounted on the surface of the electronic-component embedded resin substrate 600 to form an electronic circuit module.

However, when such a conventional electronic-component embedded resin substrate 600 is further mounted by soldering to a circuit board in an electronic apparatus or the like, through reflowing, and when it is heated, the solders 105a and 105b become molten again so as to be expanded in volume, and the solders that have become molten again have nowhere to go and thus intrude into the boundary surface between the electronic component 103 and the resin layer 106 and the boundary surface between the resin layer 106 and the core substrate 101, thereby causing the problems of short circuits between the terminal electrodes 104a and 104b and degradation of the insulation therebetween. This phenomenon is called a solder splash phenomenon.

In some cases, electronic-component embedded resin substrates and electronic circuit modules have been prevented from functioning normally, due to occurrences of such solder splash phenomena therein. Accordingly, it is important to take countermeasures against solder splash phenomena in electronic-component embedded resin substrates, and various types of countermeasures thereagainst have been taken.

For example, Japanese Unexamined Patent Publication No. 2007-142182 describes previously adding a hygroscopic filler capable of absorbing moisture to a resin to form a resin layer in an electronic-component embedded resin layer. That is, if the resin contains moisture, this moisture will be vaporized during the resin-layer formation process, thereby inducing a vacancy in the resin layer. Further, such vacancies have degraded the adhesion between the resin layer and an electronic component embedded therein and the adhesion between the resin layer and a core substrate, which has increased the possibility of occurrence of solder splash phenomena, in some cases. In focusing attention on the fact that solder splash phenomena occur through such vacancies, Japanese Unexamined Patent Publication No. 2007-142182 aims at removing moisture through the hygroscopic filler for suppressing the occurrence of vacancies, thereby to suppress the occurrence of solder splash phenomena.

On the other hand, Japanese Unexamined Patent Publication No. 2005-39158 describes defining the particle size of an inorganic filler added to a resin layer, in order to enhance the adhesion between the resin layer and an electronic component embedded therein, for suppressing the occurrence of solder splash phenomena.

However, the methods disclosed in Japanese Unexamined Patent Publication No. 2007-142182 and Japanese Unexamined Patent Publication No. 2005-39158 are intended to enhance the adhesion between the resin layer and the electronic component and the adhesion between the resin layer and the core substrate for preventing intrusions of the solders that have become molten again into the boundary surfaces between the resin layer and the electronic component and between the resin layer and the core substrate. Thus, these methods are not fundamentally intended to prevent the occurrence of solder splash phenomena. Accordingly, it has been difficult to suppress the occurrence of solder splash phenomena, in the event of the occurrence of gaps between the resin layer and the electronic component and between the resin layer and the core substrate, due to vibrations, shocks, thermal expansion differences therebetween, and the like.

### SUMMARY OF THE INVENTION

In view of the above-described problems, preferred embodiments of the present invention provide an electronic-component embedded resin substrate including a core substrate provided with a land electrode on a surface thereof; an electronic component which is provided with a terminal electrode, the terminal electrode being connected and secured by solder to the land electrode on the core substrate; and a resin layer which is arranged on the core substrate so as to cover the electronic component; wherein the resin layer includes a hollow via which extends to the solder at one end thereof and which is sealed by a sealing member at the other end thereof.

Further, the electronic-component embedded resin substrate according to a preferred embodiment of the present invention can be a so-called core-substrate-less electronic-component embedded resin substrate which includes no core substrate.

Further, in the electronic-component embedded resin substrate according to a preferred embodiment of the present invention, the hollow via can be depressurized to below the atmospheric pressure. In this case, solder that has become molten again can be reliably flowed into the hollow via and housed therein, which is more preferable.

Further, an electronic circuit module according to a preferred embodiment of the present invention can be formed by mounting an electronic component on the surface of the aforementioned electronic-component embedded resin substrate.

With the electronic-component embedded resin substrate according to a preferred embodiment of the present invention, and with the electronic circuit module including the electronic-component embedded resin substrate according to another preferred embodiment of the present invention, when they are mounted by soldering on a circuit board in an electronic-apparatus or the like, through reflowing, and when they are heated, even if the solder used for mounting the embedded electronic component becomes molten again and, thus, the solder is expanded, the solder that has become molten again can be flowed into the hollow via and housed therein. This effectively suppresses and prevents the occurrence of solder splash phenomena.

Further, after the temperature has been lowered, the solder that has become molten again bonds, again, the terminal electrode in the electronic component to the land electrode, which allows the electronic-component embedded resin substrate and the electronic circuit module to function normally.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view illustrating a first process which is performed for fabricating an electronic-component embedded resin substrate according to a first preferred embodiment of the present invention.

FIG. 2 is a cross-sectional view illustrating a second process which is performed for fabricating the electronic-component embedded resin substrate.

FIG. 3 is a cross-sectional view illustrating a third process which is performed for fabricating the electronic-component embedded resin substrate.

FIG. 4 is a cross-sectional view illustrating a fourth process which is performed for fabricating the electronic-component embedded resin substrate.

FIG. 5 is a cross-sectional view illustrating a fifth process which is performed for fabricating the electronic-component embedded resin substrate.

FIG. 6 is a cross-sectional view illustrating a sixth process which is performed for fabricating the electronic-component embedded resin substrate.

FIG. 7 is a cross-sectional view illustrating an electronic-component embedded resin substrate 100 fabricated through the processes illustrated in FIGS. 1 to 6.

FIG. 8 is a cross-sectional view illustrating an electronic circuit module 200 including the electronic-component embedded resin substrate 100 illustrated in FIG. 7.

FIG. 9 is a cross-sectional view illustrating an electronic-component embedded resin substrate 300 according to a second preferred embodiment of the present invention.

FIG. 10 is a cross-sectional view illustrating an electronic-component embedded resin substrate 400 according to a third preferred embodiment of the present invention.

FIG. 11 is a cross-sectional view illustrating an electronic-component embedded resin substrate 500 according to a fourth preferred embodiment of the present invention.

FIG. 12 is a cross-sectional view illustrating a conventional electronic-component embedded resin substrate 600.

### DETAILED DESCRIPTION OF THE PREFERRED EMBODIMENTS

Hereinafter, preferred embodiments of the present invention will be described with reference to the drawings.

### First Preferred Embodiment

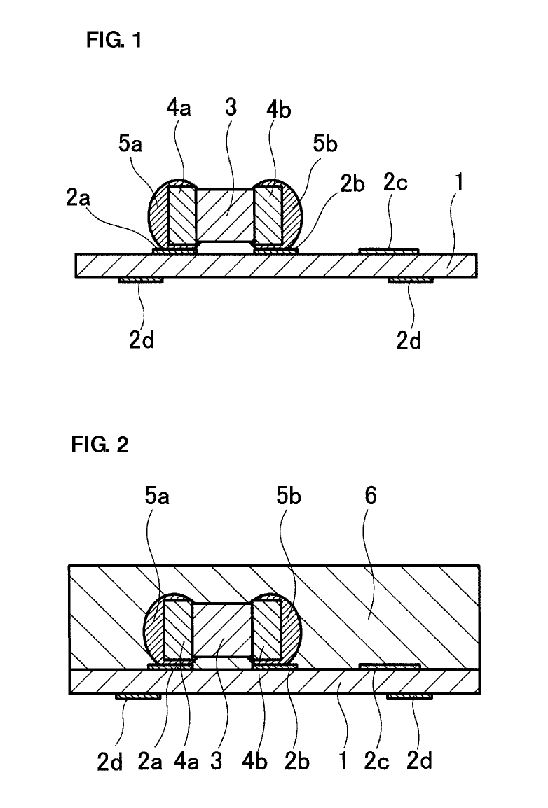

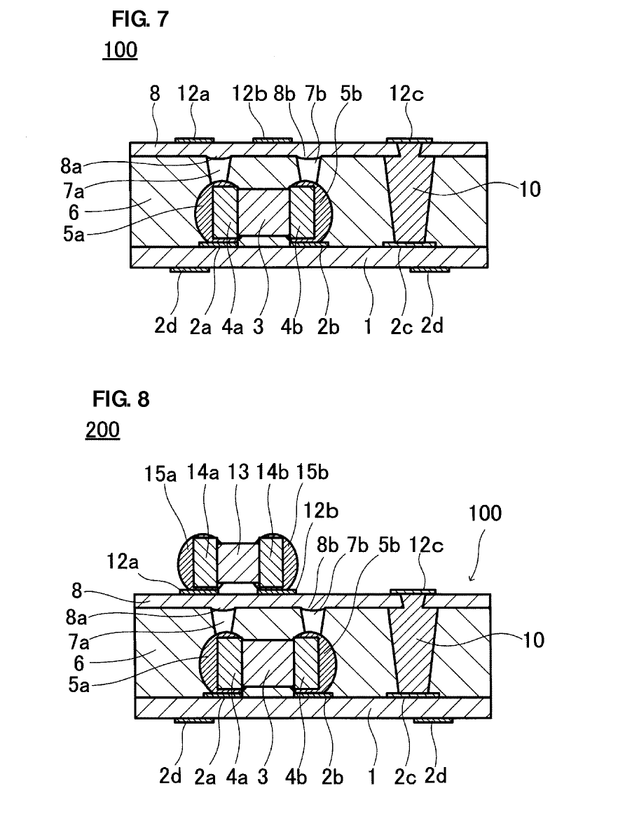

FIGS. 1 to 7 illustrate an electronic-component embedded resin substrate 100 according to a first preferred embodiment of the present invention. FIGS. 1 to 6 are cross-sectional views illustrating respective processes in an example for fabricating an electronic-component embedded resin substrate 100 according to the first preferred embodiment of the present invention, and FIG. 7 is a cross-sectional view illustrating the electronic-component embedded resin substrate 100 which has been completed.

First, as illustrated in FIG. 7, the electronic-component embedded resin substrate 100 includes a core substrate 1. The core substrate 1 can be made of ceramic or resin. Preferably, it is made of ceramic, for example.

On a surface of the core substrate 1 in the electronic-component-mounted side, there are provided land electrodes 2a and 2b to mount an electronic component thereon, and a connection electrode 2c to connect a conduction via thereto. On a surface of the core substrate 1 in the side opposite from the electronic-component mounted side, there is further provided outer connection electrodes 2d for use in mounting the completed electronic-component embedded resin substrate 100 on a circuit board in an electronic apparatus or the like. The land electrodes 2a and 2b, the connection electrode 2c, and the outer connection electrodes 2d can be made of various types of conductive materials, but they can be preferably made of copper, for example.

A chip-type electronic component 3 is embedded in the electronic-component embedded resin substrate 100. The electronic component 3 is provided with terminal electrodes 4a and 4b at its opposite ends. The electronic component 3 is mounted on the core substrate 1, through the terminal electrodes 4a and 4b which are connected and secured by solders 5a and 5b to the land electrodes 2a and 2b on the core substrate 1. The electronic component 3 can be a capacitor, a coil, or a resistor, for example, but the illustrated electronic component is intended to represent a capacitor, for example. Although FIG. 7 illustrates only one electronic component 3, a plurality of electronic components 3 of a plurality of types can be embedded together in the electronic-component embedded resin substrate 100 to provide a desired circuit therein.

A resin layer 6 is arranged on the core substrate 1 so as to cover the electronic component 3. In the present preferred embodiment, the resin layer 6 is preferably made of a thermosetting epoxy resin containing an inorganic filler, but the resin layer 6 can be made of other resins.

Hollow vias 7a and 7b are provided in the resin layer 6. The hollow vias 7a and 7b extend to the solders 5a and 5b at one ends thereof, respectively, and are sealed by a sealing-member layer 8 at the other ends thereof, thereby defining enclosed spaces within the hollow vias 7a and 7b. The interiors of the hollow vias 7a and 7b are depressurized to below the atmospheric pressure. Preferably, the pressure therein is made equal to or lower than about 1000 hPa, for example. The sealing-member layer 8 is preferably made of a thermosetting epoxy resin containing an inorganic filler, which is the same as that forming the resin layer 6. Further, expanding portions 8a and 8b of the sealing-member layer 8 which are slightly intruded into the hollow vias 7a and 7b are formed, since the resin forming the sealing-member layer 8 has been drawn into the hollow vias 7a and 7b which have been depressurized to below the atmospheric pressure.

A conduction via 10 is formed through the resin layer 6 and the sealing-member layer 8. The conduction via 10 is filled with a conductive material. It is possible to use various types of materials as the conductive material, but copper is preferably used, for example.

Wiring electrodes 12a, 12b, and 12c are provided on a surface of the sealing-member layer 8 in a side opposite from a surface which is in contact with the resin layer 6. The wiring electrodes 12a, 12b, and 12c are preferably defined by predetermined patterns, to which predetermined connections are made. The wiring electrode 12c is connected to the conduction via 10. Preferably, the wiring electrodes 12a, 12b, and 12c are also made of copper, for example.

The electronic-component embedded resin substrate 100 according to the first preferred embodiment having the aforementioned structure is fabricated according to a fabrication method as follows, for example.

First, as illustrated in FIG. 1, the electronic component 3 is mounted by soldering on the core substrate 1, through reflowing. More specifically, the terminal electrodes 4a and 4b in the electronic component 3 are connected and secured to the land electrodes 2a and 2b on the core substrate 1, by the solders 5a and 5b.

Next, as illustrated in FIG. 2, a thermosetting epoxy resin having been heated into a semi-molten state is placed on the core substrate 1 on which the electronic component 3 has been mounted, and this epoxy resin is further heated to be cured to form the resin layer 6.

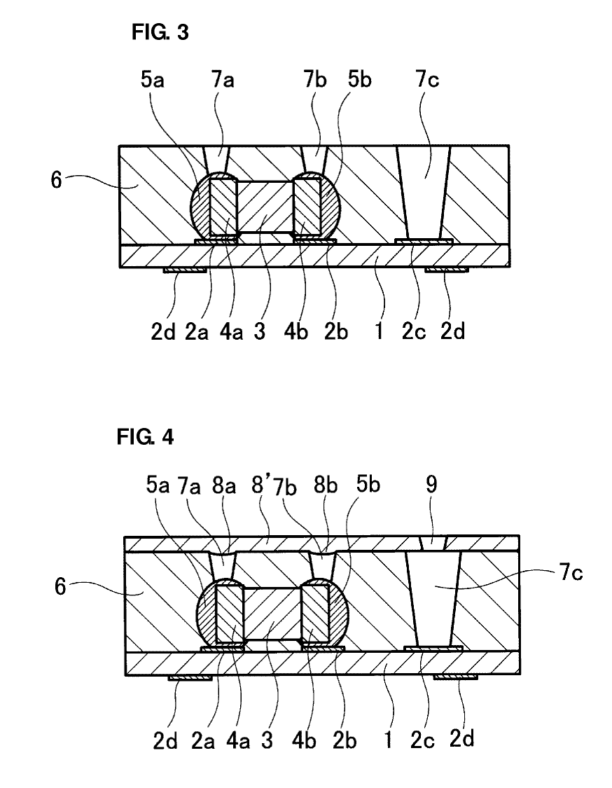

Next, as illustrated in FIG. 3, the cured resin layer 6 is irradiated with laser light to form the hollow vias 7a, 7b, and 7c. The hollow vias 7a and 7b are formed therein such that one ends thereof reach the solders 5a and 5b, while the hollow via 7c is formed such that one end thereof reaches the connection electrode 2c.

Next, as illustrated in FIG. 4, an uncured thermosetting epoxy resin sheet 8′ which has been previously provided with a hole 9 is placed on the resin layer 6. The epoxy resin sheet 8′ is placed so as to close the hollow vias 7a and 7b, and such that the hole 9 is continuous with the hollow via 7c.

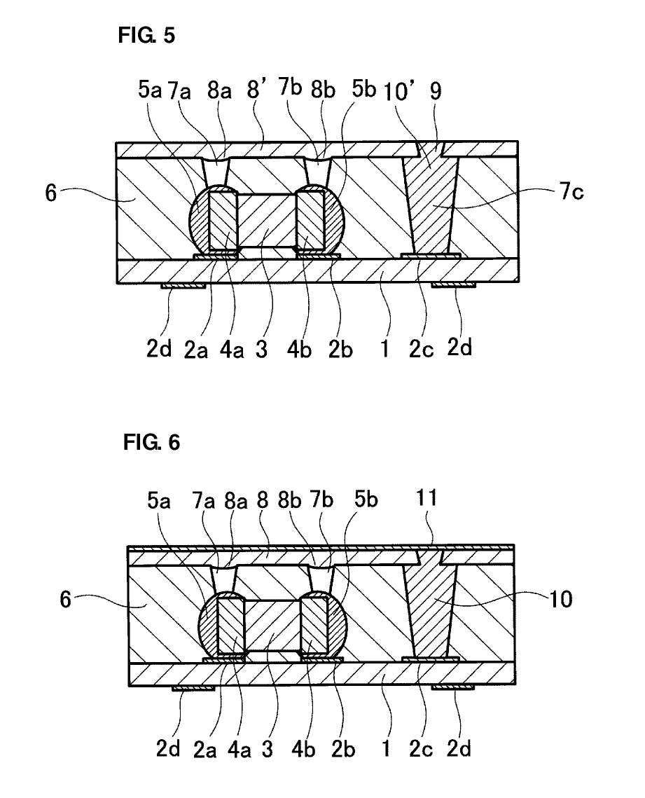

Next, as illustrated in FIG. 5, a conductive paste 10′ containing copper as a main component is charged within the hollow via 7c in the resin layer 6 and within the hole 9 in the epoxy resin sheet 8′.

Next, as illustrated in FIG. 6, a copper foil 11 is placed on the epoxy resin sheet 8′, and the copper foil 11 and the epoxy resin sheet 8′ are entirely heated so that the epoxy resin sheet 8′ is cured to form the sealing-member layer 8, and the conductive paste 10′ is burned to form a conductive via 10. Thus, by heating the entirety as described above, the resin layer 6 and the sealing-member layer 8 are bonded to each other, and the sealing-member layer 8 and the copper foil 11 are bonded to each other. This process is performed in an environment depressurized to below the atmospheric pressure. That is, by performing this process under a depressurized environment, the interiors of the sealed hollow vias 7a and 7b can be depressurized to below the atmospheric pressure.

Lastly, as illustrated in FIG. 7, patterning is performed on the copper foil 11 according to a common method to form the wiring electrodes 12a, 12b, and 12c, thereby completing the fabrication of the electronic-component embedded resin substrate 100 according to the first preferred embodiment.

While there has been described a case in which one electronic-component embedded resin substrate is fabricated, it is also possible to fabricate a plurality of electronic-component embedded resin substrates at the same time, using a larger mother substrate. In this case, the individual electronic-component embedded resin substrates should be separated from the mother substrate, after the completion of the fabrication of the electronic-component embedded resin substrates or in a predetermined process before the completion of the fabrication thereof.

The electronic-component embedded resin substrate 100 fabricated as described above can be used as a substrate for an electronic circuit module. For example, as illustrated in FIG. 8, an electronic component 13 is mounted on the surface of the electronic-component embedded resin substrate 100 to form a predetermined electronic circuit, for fabricating an electronic circuit module 200. More specifically, terminal electrodes 14a and 14b in the electronic component 13 are connected and secured to the wiring electrodes 12a and 12b by solders 15a and 15b, to form the electronic circuit module 200.

With the electronic-component embedded resin substrate 100 and the electronic circuit module 200 according to the first preferred embodiment which have been described above, when they are mounted by soldering to a circuit board in an electronic apparatus or the like through reflowing, and when they are heated, even if the solders 5a and 5b become molten again so as to be expanded in volume, the solders that have become molten again can be flowed into the hollow vias 7a and 7b, and thus, can be housed therein. This prevents the solders that have become molten again from intruding into the gap between the core substrate 1 and the resin layer 6 and the gap between the electronic component 3 and the resin layer 6, to induce a short circuit between the terminal electrodes 4a and 4b in the electronic component 3 and degradation of the insulation therebetween. Further, since the hollow vias 7a and 7b are in a sealed state, they are prevented from forming a moisture absorption path or the like, and are prevented from causing exfoliation between the resin layer 6 and the sealing-member layer 8, between the core substrate 1 and the resin layer 6, and the like.

### Second Preferred Embodiment

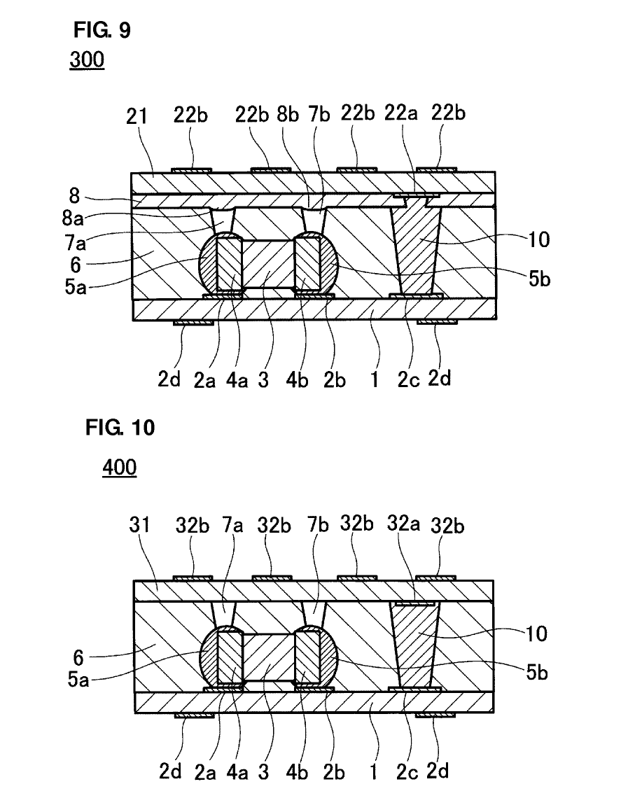

FIG. 9 illustrates an electronic-component embedded resin substrate 300 according to a second preferred embodiment of the present invention. FIG. 9 is a cross-sectional view of the electronic-component embedded resin substrate 300.

In the electronic-component embedded resin substrate according to the second preferred embodiment, a substrate 21 is further provided on a surface of a sealing-member layer 8 in a side opposite from a surface which is in contact with a resin layer 6. A connection electrode 22a to establish a connection to a conduction via 10 is provided on a portion of the substrate 21 which is in contact with the conduction via 10, and wiring electrodes 22b are provided on a surface in a side opposite from a surface which is in contact with the sealing-member layer 8. The other structures thereof are preferably the same or substantially the same as those of the electronic-component embedded resin substrate 100 according to the first preferred embodiment.

The electronic-component embedded resin substrate 300 according to the second preferred embodiment can be fabricated as follows. For example, the substrate 21 which has been previously provided with the connection electrode 22a and the wiring electrodes 22b is placed on an uncured resin sheet intended to form the sealing-member layer 8, and they are then heated so that the resin sheet is cured to form the sealing-member layer 8, and further, a conductive paste is burned therein to form the conduction via 10. By heating as described above, the resin layer 6 and the sealing-member layer 8 are bonded to each other, the sealing-member layer 8 and the substrate 21 are bonded to each other, and conduction is established between the conduction via 10 and the connection electrode 22a.

### Third Preferred Embodiment

FIG. 10 illustrates an electronic-component embedded resin substrate 400 according to a third preferred embodiment of the present invention. FIG. 10 is a cross-sectional view of the electronic-component embedded resin substrate 400.

In the electronic-component embedded resin substrate 400 according to the third preferred embodiment, a substrate 31 is directly bonded, through an adhesive agent (not illustrated), to a surface of a resin layer 6 in the side opposite from the surface which is in contact with a core substrate 1. That is, in the present preferred embodiment, the substrate 31 serves as a sealing member to seal hollow vias 7a and 7b. A connection electrode 32a to establish a connection to a conduction via 10 is provided on the surface of the substrate 31 which is in contact with the resin layer 6, and wiring electrodes 32b is provided on the surface in the side opposite from the surface which is in contact with the resin layer 6. The other structures thereof are preferably the same or substantially the same as those of the electronic-component embedded resin substrate 100 according to the first preferred embodiment.

The electronic-component embedded resin substrate 400 according to the third preferred embodiment can be fabricated as follows. For example, the substrate 31 having been previously provided with the connection electrode 32a and the wiring electrodes 32b is bonded to the resin layer 6 by an adhesive agent, and thereafter heated. Through the heating, a conductive paste is burned therein to form the conduction via 10, and conduction is established between the conduction via 10 and the connection electrode 32a.

### Fourth Preferred Embodiment

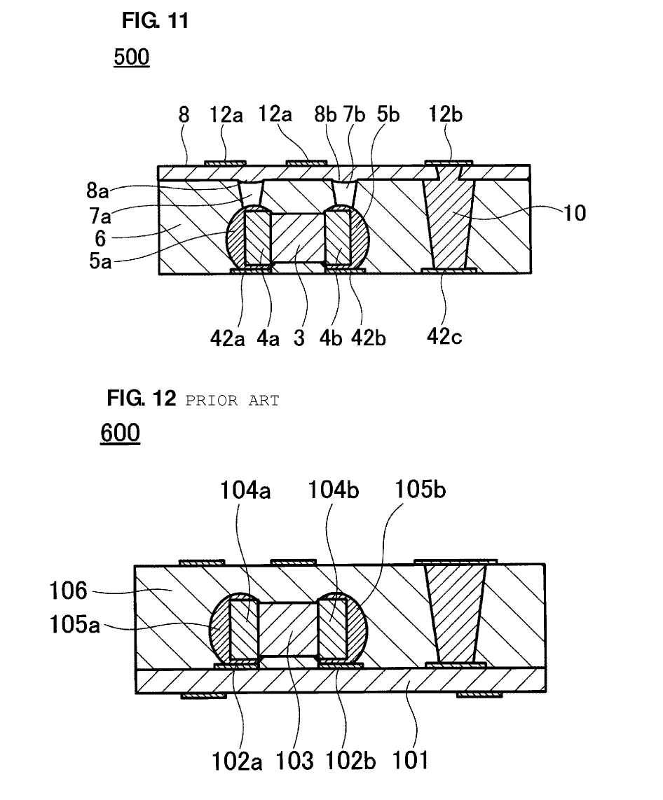

FIG. 11 illustrates an electronic-component embedded resin substrate 500 according to a fourth preferred embodiment of the present invention. FIG. 11 is a cross-sectional view of the electronic-component embedded resin substrate 500.

The electronic-component embedded resin substrate 500 according to the fourth preferred embodiment preferably is a so-called core-substrate-less electronic-component embedded resin substrate which includes no core substrate.

As illustrated in FIG. 11, terminal electrodes 4a and 4b in an embedded electronic component 3 is connected and secured, through solders 5a and 5b, to land electrodes 42a and 42b which are exposed in the surface of a resin layer 6. Further, a conduction via 10 is connected to a land electrode 42c which is exposed in the surface of the resin layer 6. The other structures thereof are preferably the same or substantially the same as those of the electronic-component embedded resin substrate 100 according to the first preferred embodiment.

The electronic-component embedded resin substrate 500 according to the fourth preferred embodiment can be fabricated as follows. For example, a jig substrate (not illustrated) intended to be used only for the fabrication is prepared, the land electrodes 42a, 42b, and 42c are formed on the surface of the jig substrate, and the electronic component 3 is mounted to the land electrodes 42a and 42b. Thereafter, the fabrication of the electronic-component embedded resin substrate 500 is completed according to the same fabrication method as the fabrication method described in the first preferred embodiment. Lastly, the completed electronic-component embedded resin substrate 500 is disengaged from the jig substrate.

By forming the electronic-component embedded resin substrate 500 in a core-substrate-less manner as in the fourth preferred embodiment, it is possible to achieve the advantages of reduction of the thickness of the electronic-component embedded resin substrate 500, reduction of the material cost, and the like.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic-component embedded resin substrate comprising:
a core substrate provided with a land electrode on a surface thereof;
an electronic component provided with a terminal electrode, the terminal electrode being connected and secured by solder to the land electrode on the core substrate; and
a resin layer arranged on the core substrate so as to cover the electronic component; wherein
the resin layer includes a hollow via which extends to the solder at a first end thereof; and
the electronic-component embedded resin substrate further includes a sealing member arranged to seal the hollow via at a second end thereof.

2. The electronic-component embedded resin substrate according to claim 1, wherein the hollow via is depressurized to below an atmospheric pressure.

3. The electronic-component embedded resin substrate according to claim 2, wherein an air pressure in the hollow via which is depressurized to below the atmospheric pressure is equal to or lower than about 1000 hPa.

4. The electronic-component embedded resin substrate according to claim 1, wherein the resin layer includes a conduction via which is interiorly filled with a conductive material, in addition to the hollow via.

5. The electronic-component embedded resin substrate according to claim 1, wherein the sealing member is made of a material identical to that of the resin layer.

6. The electronic-component embedded resin substrate according to claim 1, further comprising a wiring pattern provided on a surface of the sealing member on a side opposite from a surface sealing the hollow via.

7. The electronic-component embedded resin substrate according to claim 1, further comprising a substrate provided on a surface of the sealing member on a side opposite from a surface sealing the hollow via.

8. An electronic circuit module comprising;
the electronic-component embedded resin substrate according to claim 1; and
an electronic component mounted on a surface of the electronic-component embedded resin substrate.

9. An electronic-component embedded resin substrate comprising:
a land electrode;
an electronic component provided with a terminal electrode, the terminal electrode being connected and secured to the land electrode by solder; and
a resin layer arranged to cover the electronic component, the resin layer having the land electrode exposed in a surface thereof; wherein
the resin layer includes a hollow via which extends the solder at a first end thereof; and
the electronic-component embedded resin substrate further includes a sealing member arranged to seal the hollow via at a second end thereof.

10. The electronic-component embedded resin substrate according to claim 9, wherein the hollow via is depressurized to below an atmospheric pressure.

11. The electronic-component embedded resin substrate according to claim 10, wherein an air pressure in the hollow via which is depressurized to below the atmospheric pressure is equal to or lower than about 1000 hPa.

12. The electronic-component embedded resin substrate according to claim 9, wherein the resin layer includes a conduction via which is interiorly filled with a conductive material, in addition to the hollow via.

13. The electronic-component embedded resin substrate according to claim 9, wherein the sealing member is made of a material identical to that of the resin layer.

14. The electronic-component embedded resin substrate according to claim 9, further comprising a wiring pattern provided on a surface of the sealing member on a side opposite from a surface sealing the hollow via.

15. The electronic-component embedded resin substrate according to claim 9, further comprising a substrate provided on a surface of the sealing member on a side opposite from a surface sealing the hollow via.

16. An electronic circuit module comprising;
the electronic-component embedded resin substrate according to claim 9; and
an electronic component mounted on a surface of the electronic-component embedded resin substrate.
